(19) United States
(12) Patent Application Publication
(10) Pub. No.: US 2026/0038607 A1
(43) Pub. Date: Feb. 5, 2026

(54) TEMPERATURE-BASED READ DISTURB OPERATIONS

(71) Applicant: Micron Technology, Inc., Boise, ID (US)

(72) Inventors: Murong LANG, San Jose, CA (US); Chao-Han CHENG, San Jose, CA (US); Zhenming ZHOU, San Jose, CA (US)

(21) Appl. No.: 18/788,467

(22) Filed: Jul. 30, 2024

(51) Int. Cl. G11C 16/34; G11C 16/08; G11C 29/52

(52) U.S. Cl. CPC G11C 16/3418; G11C 16/08; G11C 29/52

(57) ABSTRACT

In some implementations, a memory system may identify, based on a determination that a counter satisfies a first threshold, a temperature associated with the one or more memory devices. The memory system may selectively perform a first one or more read disturbance operations or perform a second one or more read disturbance operations based on whether the temperature satisfies a second threshold, the first one or more read disturbance operations comprising a first type of page scan associated with a first one or more word lines of the one or more memory devices, and the second one or more read disturbance operations comprising a second type of page scan associated with a second one or more word lines of the one or more memory devices.

### TECHNICAL FIELD

The present disclosure generally relates to memory devices, memory device operations, and, for example, to temperature-based read disturb operations.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of temperature-based read disturb operations.

FIG. 2 is a diagram illustrating an example memory architecture that may be used by the memory device.

FIG. 3 is a diagram illustrating an example of components included in a memory device.

FIG. 4 is a diagram illustrating an example of read errors that may occur in a multi-level cell (MLC) non-volatile memory device.

FIG. 5 is a diagram of an example of temperature-based read disturb operations.

FIG. 6 is a diagram of an example of temperature-based read disturb operations.

FIG. 7 is a flowchart of an example method associated with temperature-based read disturb operations.

FIG. 8 is a flowchart of an example method associated with temperature-based read disturb operations.

FIG. 9 is a flowchart of an example method associated with temperature-based read disturb operations.

### DETAILED DESCRIPTION

Some memory systems, such as memory devices in automotive systems, may be subject to high temperature environments. Such environments may introduce or amplify challenges to maintain the integrity of data stored in a memory system, such as degradation of data integrity due to read disturbance charge gain and/or read disturbance induced charge loss. As used herein, “read disturbance” refers to a change in the voltage level of a memory cell due to reading a word line that includes the memory cell and/or reading a word line that is near the memory cell. At lower temperatures (e.g., at temperatures at or below around 30 degrees Celsius), a memory cell may be more likely to experience read disturbance charge gain and may be less likely to experience read disturbance induced charge loss. Alternatively, at higher temperatures (e.g., at temperatures at or above 30 degrees Celsius), a memory cell may be more likely to experience read disturbance induced charge loss and may be less likely to experience read disturbance charge gain.

Some memory systems may implement one or more memory management operations (e.g., read disturbance operations) to mitigate read disturb degradation. For example, a memory system may implement a counter to track a quantity of access operations performed by the memory system. If the counter satisfies a threshold, the memory system may read data from a block of memory cells and determine an error rate associated with the data. If the error rate satisfies an error threshold, then the memory system may transfer data from the block to a separate block (e.g., may fold data from the block to the separate block).

However, such memory systems may not account for the temperature dependence of the likelihood of different errors (e.g., errors caused by read disturbance charge gain and/or errors caused by read disturbance induced charge loss). Said another way, such memory systems may perform read disturbance operations at the same rate, regardless of temperature. Accordingly, such memory systems may inefficiently manage read disturb operations. For example, at lower temperatures, read errors due to read disturbance induced charge loss may be less likely, and the memory system may perform read disturbance operations at a higher rate than is needed to address errors caused by read disturbance induced charge loss, thus wasting system resources. Alternatively, at higher temperatures, read errors due to read disturbance induced charge loss may be more likely, and the rate at which the memory system performs read disturbance operations may be too low to address such errors, which may reduce the integrity of data stored to the memory system.

Some implementations as described herein may enable temperature-based read disturbance operations. For example, a memory system may maintain a counter to track a quantity of read operations performed by the memory system. As part of performing a read operation (e.g., a read operation associated with a read command received from a host system and/or a read operation associated with an internal read command), the memory system may modify (e.g., increase by one or more amounts, as described herein) the value of the access counter. If the value of the counter satisfies an access threshold, then the memory system may perform the one or more read disturbance operations. The amount by which the memory system modifies the counter may be based on a temperature of the memory system. For example, if the temperature satisfies a threshold (e.g., if the temperature is high), then the memory system may increase the counter by a first value. Alternatively, if the temperature does not satisfy the threshold (e.g., if the temperature is low), then the memory system may increase the counter by a second value that is less than the first value.

In some examples, the memory system may initiate one or more read disturbance operations based on the value of the counter satisfying a threshold. In such examples, the memory system may selectively perform a first type of page scan or a second type of page scan based on the temperature. For example, if the temperature satisfies a threshold (e.g., if the temperature is high), then the memory system may perform one or more first read disturbance operations using the first type of page scan, and may refrain from performing read disturbance operations using the second type of page scan. Alternatively, if the temperature does not satisfy the threshold (e.g., if the temperature is low), then the memory system may perform one or more second read disturbance operations using the second type of page scan, and may refrain from performing read disturbance operations using the first type of page scan. As described in greater detail elsewhere herein, the first type of page scan may be more sensitive to errors caused by read disturbance induced charge loss than the second type of page scan.

By enabling temperature-based read disturbance operations, the memory system may improve the efficiency of read disturbance operations. For example, by selectively increasing the counter by a first value or by a second value less than the first value based on temperature, the memory system may perform read disturbance operations more frequently (e.g., if the temperature is high), which may increase the likelihood of identifying read errors caused by read disturbance induced charge loss. Accordingly, the memory system may more reliably address such errors, and thus improve the integrity of data stored to the memory system. Alternatively, if the temperature is low, then the memory system may perform read disturbance operations less frequently, which may reduce the processing load on the memory system and thus improve performance associated with performing other operations, such as host read and/or host write operations.

Additionally, selectively performing the first type of page scan or the second type of page scan based on the temperature may improve the efficiency and/or effectiveness of read disturb operations. For example, because the first type of page scan may be more sensitive to page errors caused by read disturbance induced charge loss, the memory system may more reliably address such errors at high temperatures, and thus improve the integrity of data stored to the memory system. Alternatively, by refraining from performing the first type of page scan at low temperatures, the memory system may reduce the quantity of read disturbance operations performed, which may reduce the processing load on the memory system and thus improve performance associated with performing other operations, such as host read and/or host write operations.

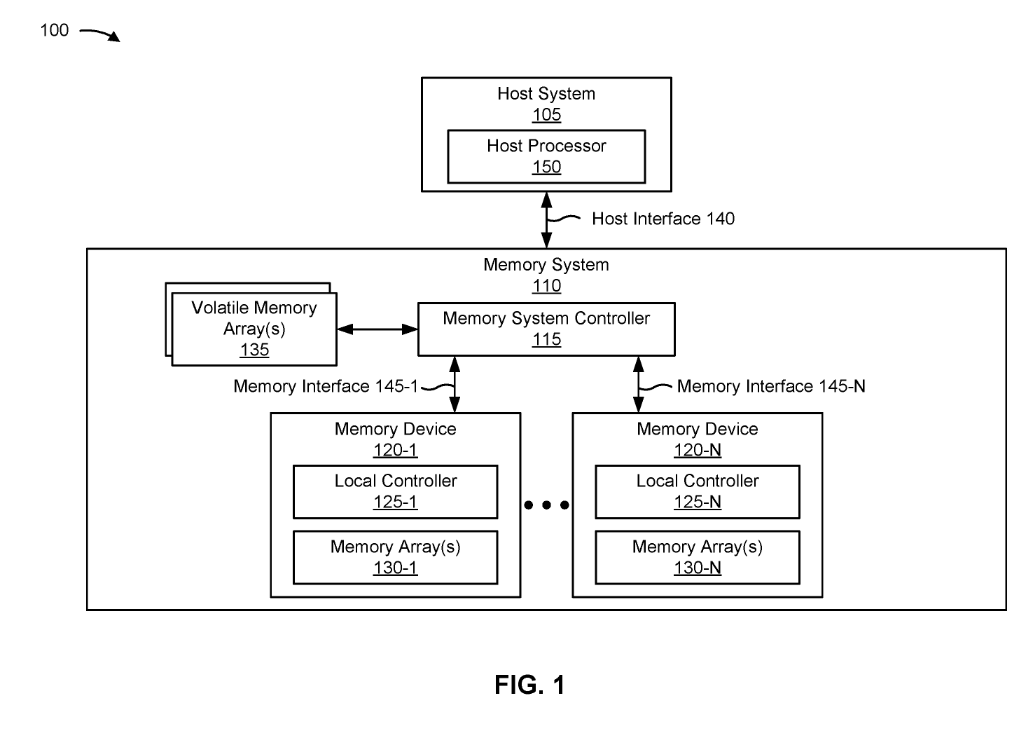

FIG. 1 is a diagram illustrating an example system 100 capable of temperature-based read disturb operations. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N ≥ 1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N ≥ 1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to: determine whether a counter associated with a quantity of read operations performed by the one or more memory devices satisfies a first threshold; identify, based on a determination that the counter satisfies the first threshold, a temperature associated with the one or more memory devices; and selectively perform a first one or more read disturbance operations or perform a second one or more read disturbance operations based on whether the temperature satisfies a second threshold, the first one or more read disturbance operations comprising a first type of page scan associated with a first one or more word lines of the one or more memory devices, and the second one or more read disturbance operations comprising a second type of page scan associated with a second one or more word lines of the one or more memory devices.

In some implementations, one or more systems, devices, apparatuses, components, and/or controllers of FIG. 1 may be configured to: perform a read operation associated with a word line of the one or more memory devices; identify a temperature associated with the one or more memory devices based on the performance of the read operation; and selectively modify based on a comparison of the temperature to a threshold, a counter associated with a quantity of read operations.

In some implementations, one or more systems, devices, apparatuses, components, and/or controllers of FIG. 1 may be configured to determine whether a counter associated with a quantity of read operations performed by one or more memory devices satisfies a first threshold; identify, based on determining that the counter satisfies the first threshold, a temperature associated with the one or more memory devices; and selectively identify a first one or more error rates using one or more page scans having a first type, the first one or more error rates associated with a first one or more pages of the one or more memory devices or identifying a second one or more error rates using one or more page scans having a second type, the second one or more error rates associated with a second one or more pages of the one or more memory devices based on determining whether the temperature satisfies a second threshold.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

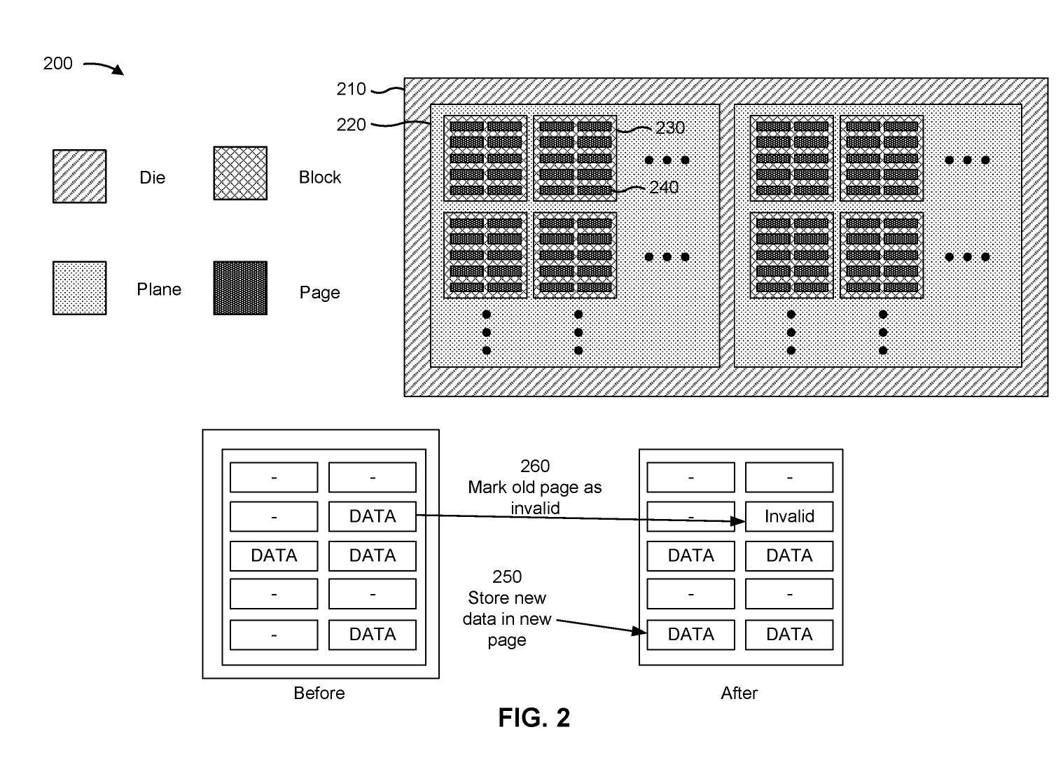

FIG. 2 is a diagram illustrating an example memory architecture 200 that may be used by the memory device 120. The memory device 120 may use the memory architecture 200 to store data. As shown, the memory architecture 200 may include a die 210, which may include multiple planes 220. A plane 220 may include multiple blocks 230. A block 230 may include multiple pages 240. Although FIG. 2 shows a particular quantity of planes 220 per die 210, a particular quantity of blocks 230 per plane 220, and a particular quantity of pages 240 per block 230, these quantities may be different than what is shown. In some implementations, the memory architecture 200 is a NAND memory architecture.

The die 210 is a structure made of semiconductor material, such as silicon. In some implementations, a die 210 is the smallest unit of memory that can independently execute commands. A memory device 120 may include one or more dies 210. In some implementations, the memory device 120 may include multiple dies 210. In this case, multiples dies 210 may each perform a respective memory operation (e.g., a read operation, a write operation, or an erase operation) in parallel. For example, a controller 125 of the memory device 120 may be configured to concurrently perform memory operations on multiple dies 210 for parallel control.

Each die 210 of a memory device 120 includes one or more planes 220. A plane 220 is sometimes called a memory plane. In some implementations, identical and concurrent operations can be performed on multiple planes 220 (sometimes with restrictions). For example, a multi-plane command (e.g., a multi-plane read command or a multi-plane write command) may be executed on multiple planes 220 concurrently, whereas a single plane command (e.g., a single plane read command or a single plane write command) may be executed on a single plane 220. A logical unit of the memory device 120 may include one or more planes 220 of a die 210. In some implementations, a logical unit may include all planes 220 of a die 210 and may be equivalent to a die 210. Alternatively, a logical unit may include fewer than all planes 220 of a die 210. A logical unit may be identified by a logical unit number (LUN). Depending on the context, the term “LUN” may refer to a logical unit or an identifier (e.g., a number) of that logical unit.

Each plane 220 includes multiple blocks 230. A block 230 is sometimes called a memory block. Each block 230 includes multiple pages 240. A page 240 is sometimes called a memory page. A block 230 is the smallest unit of memory that can be erased. In other words, an individual page 240 of a block 230 cannot be erased without erasing every other page 240 of the block 230. A page 240 is the smallest unit of memory to which data can be written (i.e., the smallest unit of memory that can be programmed with data). The terminology “programming” memory and “writing to” memory may be used interchangeably. A page 240 may include multiple memory cells that are accessible via the same access line (sometimes called a word line). In some implementations, a block 230 may be divided into multiple sub-blocks. A sub-block is a portion of a block 230 and may include a subset of pages 240 of the block and/or a subset of memory cells of the block 230.

In some implementations, read and write operations are performed for a specific page 240, while erase operations are performed for a block 230 (e.g., all pages 240 in the block 230). In some implementations, to prevent wearing out of memory, all pages 240 of a block 230 may be programmed before the block 230 is erased to enable a new program operation to be performed to a page 240 of the block 230. After a page 240 is programmed with data (called “old data” below), that data can be erased, but that data cannot be overwritten with new data prior to being erased. The erase operation would erase all pages 240 in the block 230, and erasing the entire block 230 every time that new data is to replace old data would quickly wear out the memory cells of the block 230. Thus, rather than performing an erase operation, the new data may be stored in a new page (e.g., an empty page), as shown by reference number 250, and the old page that stores the old data may be marked as invalid, as shown by reference number 260. The memory device 120 may then point operations associated with the data to the new page (e.g., in an address table) and may track invalid pages to prevent program operations from being performed on invalid pages prior to an erase operation.

When a block 230 satisfies an erasure condition, the memory device 120 may select the block 230 for erasure, copy the valid data of the block 230 (e.g., to a new block 230 or to the same block 230 after erasure), and erase the block 230. For example, the erasure condition may be that all pages 240 of the block 230 or a threshold quantity or percentage of pages 240 of the block 230 are unavailable for further programming (e.g., are either invalid or already store valid data). As another example, the erasure condition may be that a quantity or percentage of free pages 240 of the block 230 (e.g., pages 240 that are available to be written) is less than or equal to a threshold. The process of selecting a block 230 satisfying an erasure condition, copying valid pages 240 of that block 230 to a new block 230 (or the same block 230 after erasure), and erasing the block 230 is sometimes called garbage collection and is used to free up memory space of the memory device 120.

In some examples, a memory device 120 may maintain a counter to track a quantity of read operations performed by the memory device 120. As part of performing a read operation (e.g., a read operation associated with a read command received from a host system and/or a read operation associated with an internal read command), the memory device 120 may modify (e.g., increase by one or more amounts, as described herein) the value of the access counter. If the value of the counter satisfies an access threshold, then the memory device 120 may perform the one or more read disturbance operations. The amount by which the memory device 120 modifies the counter may be based on a temperature of the memory system. For example, if the temperature satisfies a threshold (e.g., if the temperature is high), then the memory device 120 may increase the counter by a first value. Alternatively, if the temperature does not satisfy the threshold (e.g., if the temperature is low), then the memory device 120 may increase the counter by a second value that is less than the first value.

In some examples, the memory device 120 may maintain multiple access counters. For example, the memory device 120 may maintain one or more counters corresponding to each die 210 of the memory device 120, one or more counters corresponding to each plane 220 of the memory device 120, and/or one or more counters corresponding to each block of the memory device 120.

As indicated above, FIG. 2 is provided as an example. Other examples may differ from what is described with regard to FIG. 2.

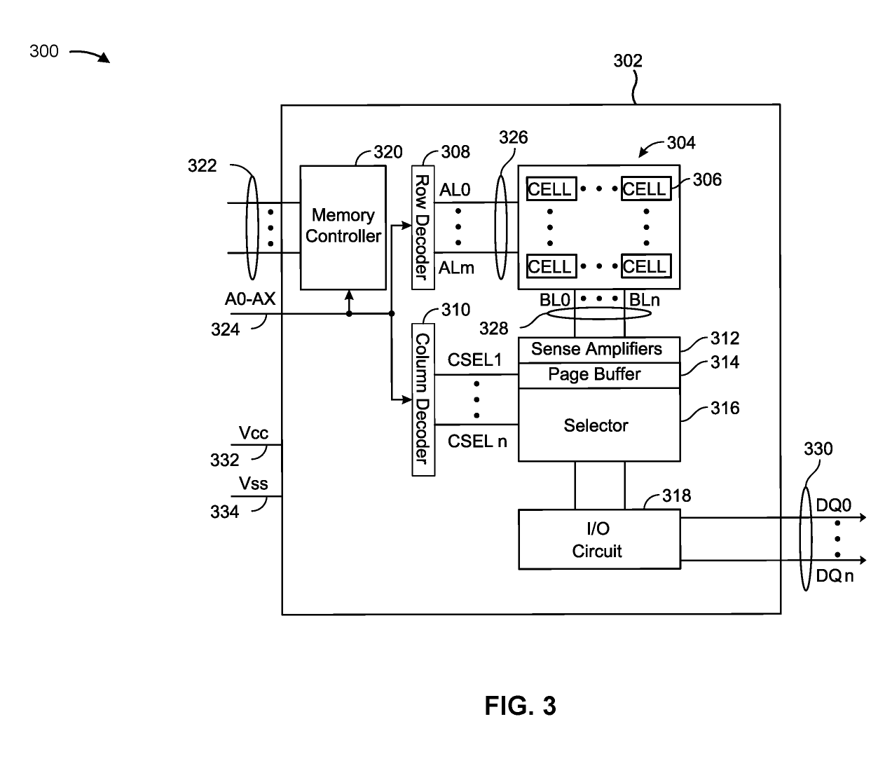

FIG. 3 is a diagram illustrating an example 300 of components included in a memory device 302. The memory device 302 may be the memory device 120. The memory device 302 may include a memory array 304 having multiple memory cells 306. The memory device 302 may include one or more components (e.g., circuits) to transmit signals to or perform memory operations on the memory array 304. For example, the memory device 302 may include a row decoder 308, a column decoder 310, one or more sense amplifiers 312, a page buffer 314, a selector 316, an input/output (I/O) circuit 318, and a memory controller 320. The memory controller 320 may be the controller 115.

The memory controller 320 may control memory operations of the memory device 302 according to one or more signals received via one or more control lines 322, such as one or more clock signals or control signals that indicate an operation (e.g., write, read, or erase) to be performed. Additionally, or alternatively, the memory controller 320 may determine one or memory cells 306 upon which the operation is to be performed based on one or more signals received via one or more address lines 324, such as one or more address signals (shown as A0-AX). A host device external from the memory device 302 may control the values of the control signals on the control lines 322 and/or the address signals on the address line 324.

The memory device 302 may use access lines 326 (sometimes called word lines or row lines, and shown as AL0-ALm) and bit lines 328 (sometimes called digit lines or column lines, and shown as BL0-BLn) to transfer data to or from one or more of the memory cells 306. For example, the row decoder 308 and the column decoder 310 may receive and decode the address signals (A0-AX) from the address line 324 and may determine which of the memory cells 306 are to be accessed based on the address signals. The row decoder 308 and the column decoder 310 may provide signals to those memory cells 306 via one or more access lines 326 and one or more bit lines 328, respectively. In some implementations, the access lines 326 may be physically arranged as a sequence of rows. Accordingly, a given access line 326, such as ALn, may have one or a pair of neighboring access lines, such as ALn-1 and/or ALn+1. Said another way, a given access line 326 (e.g., ALn) may be associated with a first adjacent access line 326 that is immediately before the given access line in the sequence of rows (e.g., ALn-1), and may be associated with a second adjacent access line 326 that is immediately after the given access line 326 in the sequence of rows (e.g., ALn+1). Due to the physical proximity of neighboring access lines 326, an access operation on a given access line 326 may induce noise on adjacent (e.g., neighboring) access lines 326.

For example, the column decoder 310 may receive and decode address signals into one or more column select signals (shown as CSEL1-CSELn). The selector 316 may receive the column select signals and may select data in the page buffer 314 that represents values of data to be read from or to be programmed into memory cells 306. The page buffer 314 may be configured to store data received from a host device before the data is programmed into relevant portions of the memory array 304, or the page buffer 314 may store data read from the memory array 304 before the data is transmitted to the host device. The sense amplifiers 312 may be configured to determine the values to be read from or written to the memory cells 306 using the bit lines 328. For example, in a selected string of memory cells 306, a sense amplifier 312 may read a logic level in a memory cell 306 in response to a read current flowing through the selected string to a bit line 328. The I/O circuit 318 may transfer values of data into or out of the memory device 302 (e.g., to or from a host device), such as into or out of the page buffer 314 or the memory array 304, using I/O lines 330 (shown as (DQ0-DQn)).

The memory controller 320 may generate or receive positive and negative supply signals, such as a supply voltage (Vcc) 332 and a negative supply (Vss) 334 (e.g., a ground potential), from an external source or power supply (e.g., an internal battery, an external battery, and/or an AC-to-DC converter).

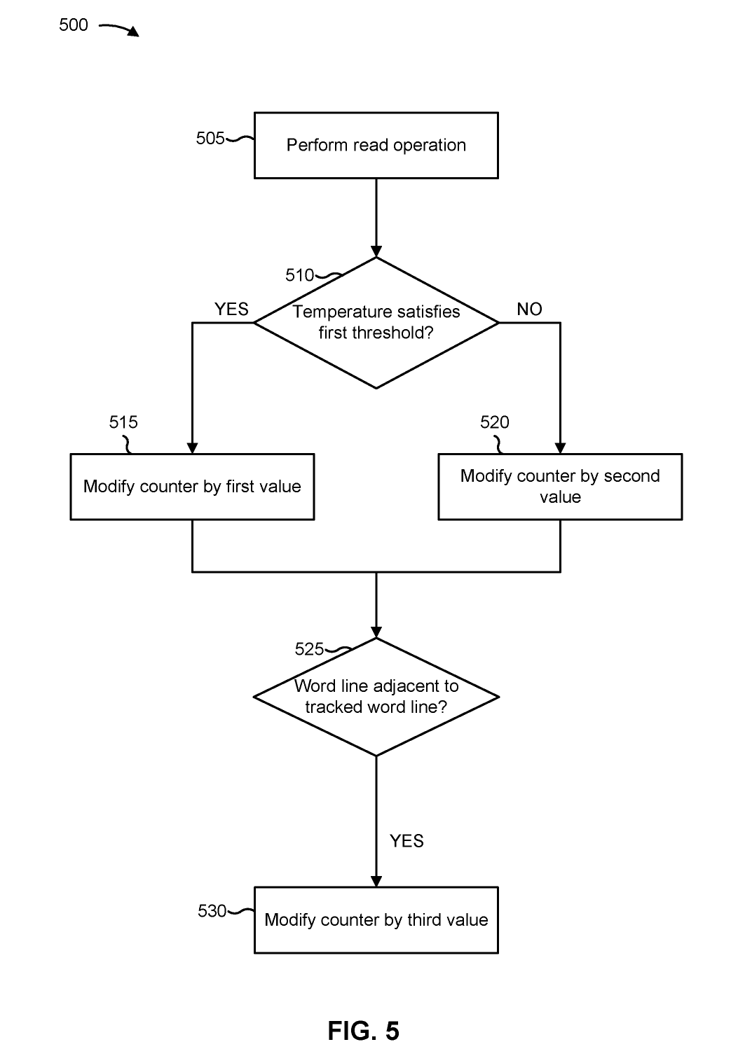

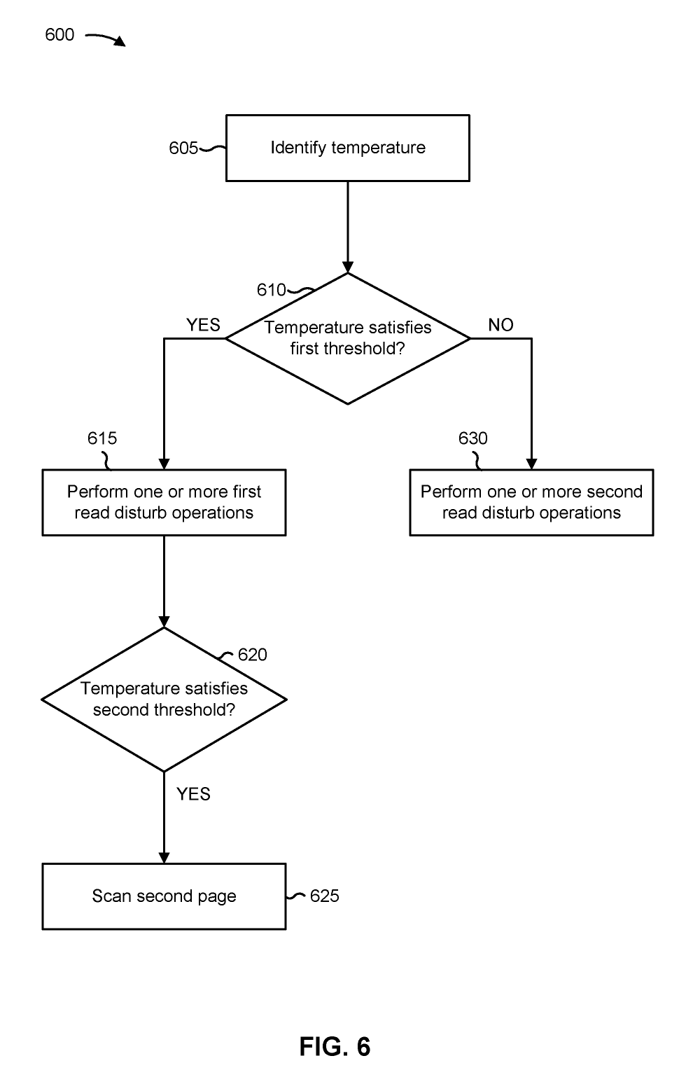

One or more devices or components shown in FIG. 3 may be used to carry out operations described elsewhere herein, such as one or more operations of FIGS. 5 and 6.

As indicated above, FIG. 3 is provided as an example. Other examples may differ from what is described with regard to FIG. 3.

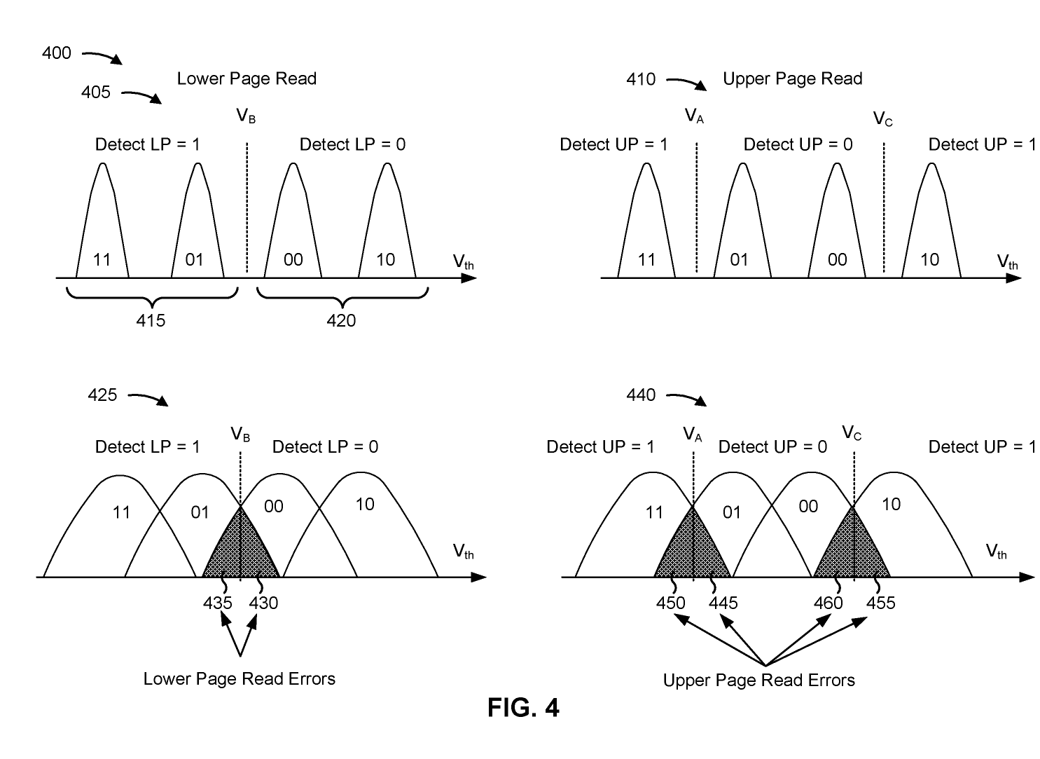

FIG. 4 is a diagram illustrating an example 400 of read errors that may occur in a multi-level cell (MLC) non-volatile memory device. Although the read errors described in connection with FIG. 4 are described in the context of an MLC, the described concepts also apply to other types of memory cells, such as single-level cells (SLCs), triple-level cells (TLCs), quad-level cells (QLCs), and other types of memory cells.

Some memory devices may be capable of storing multiple bits per memory cell. For example, an MLC non-volatile memory device (e.g., an MLC flash device) may be capable of storing two bits of information per memory cell in one of four states (e.g., may store binary 11, binary 01, binary 00, or binary 10 depending on a charge applied to the memory cell). To read the data of a memory cell, such as the MLC shown in FIG. 4, the memory device (or a component thereof) may apply a read reference voltage to the cell in an effort to induce current in the memory cell, and the memory device (or a component thereof) may determine a corresponding bit string associated with a voltage that induced (or else did not induce) current. Put another way, the memory device may apply various read reference voltages to sense the threshold voltage (Vth) associated with the data stored in the cell.

More particularly, for an MLC, the memory device may perform a lower page (also shown as LP) read and an upper page (also shown as UP) read. As shown by reference number 405, for a lower page read, the memory device may apply to a read reference voltage, shown as V_{B}. V_{B} may represent a voltage between threshold voltage distributions associated with the first two states (e.g., threshold voltage distributions associated with binary 11 and 01) and threshold voltage distributions associated with the second two states (e.g., threshold voltage distributions associated with binary 00 and 10). If current flows when V_{B} is applied to the memory cell, then the threshold voltage may be considered to be less than V_{B}, thus corresponding to one of binary 11 or binary 01 (meaning that the lower page data represents a “1”). If current does not flow when V_{B} is applied to the memory cell, then the threshold voltage may be considered to be more than V_{B}, thus corresponding to one of binary 00 or binary 10 (meaning that the lower page data represents a “0”).

As shown by reference number 410, an upper page read may be performed in a similar manner. More particularly, when the detected lower page data is a “1”, a read reference voltage of V_{A} may be applied to the memory cell to thereafter determine the upper page data. V_{A} may represent a voltage between a threshold voltage distribution associated with the first state (e.g., a threshold voltage distribution associated with binary 11) and a threshold voltage distribution associated with the second state (e.g., a threshold voltage distribution associated with binary 01). If current flows when V_{A} is applied to the memory cell, then the threshold voltage may be considered to be less than V_{A}, thus corresponding to binary 11 (meaning that the upper page data represents a “1”). If current does not flow when V_{A} is applied to the memory cell, then the threshold voltage may be considered to be more than V_{A} but less than V_{B} (as determined during the lower page read), thus corresponding to binary 01 (meaning that the upper page data represents a “0”).

Similarly, when the detected lower page data is a “0,” a read reference voltage of V_{C} may be applied to the memory cell to thereafter determine the upper page data. V_{C} may represent a voltage between a threshold voltage distribution associated with the third state (e.g., a threshold voltage distribution associated with binary 00) and a threshold voltage distribution associated with the fourth state (e.g., a threshold voltage distribution associated with binary 10). If current flows when V_{C} is applied to the memory cell, then the threshold voltage may be considered to be less than V_{C} but more than V_{B} (as determined during the lower page read), thus corresponding to binary 00 (meaning that the upper page data represents a “0”). If current does not flow when V_{C} is applied to the memory cell, then the threshold voltage may be considered to be more than V_{C}, thus corresponding to binary 10 (meaning that the upper page data represents a “1”).

In some cases, the threshold voltage distributions shown in FIG. 4 may be broadened due to noise or the like, which may lead to read errors at the memory device. Noise in the memory cell may be caused by various sources, such as program-erase (P/E) cycling stress, charge leakage over time, read disturbances (e.g., disturbances caused by the application of a high voltage to a memory cell of a page not being read to deselect the cell while other cells on the page are being read), programming errors, cell-to-cell interference (such as unintentional electrical disturbance and/or interference of a memory cell when neighboring cells are read, written, or erased), or the like. Particularly, noise caused by read disturbances may result in different changes in the voltage of a memory cell based on the temperature of the memory cell and/or the state stored by the memory cell. For example, at low temperatures, read disturbance charge gain may cause the voltage of a memory cell storing a state associated with a voltage range 415 (e.g., a memory cell storing a binary 11, a memory cell storing a binary 01) to increase. Additionally, at high temperatures, read disturbance induced charge loss may cause the voltage of a memory cell storing a state associated with a voltage range 420 (e.g., a memory cell storing a binary 00, a memory cell storing a binary 10) to decrease. As shown in FIG. 4, broadened voltage threshold distributions may lead to read errors, such as lower page read errors and/or upper page read errors.

First, as shown by reference number 425, a lower page read error may be caused by the broadening of voltage distributions that are near V_{B} and/or that overlap with V_{B}. In the example shown in FIG. 4, the threshold voltage distributions associated with binary 01 and binary 00 have broadened to overlap with the read reference voltage V_{B}. This may result in a lower page read error because a cell programmed with binary 01 may act in a similar manner to a cell programmed with binary 00 (e.g., in response to an applied voltage). More particularly, if V_{B} is applied to a memory cell that stores binary 01 but that is associated with a threshold voltage in the area labeled with reference number 430, no current would flow, erroneously indicating that the lower page data represents a “0” rather than a “1”. On the other hand, if V_{B} is applied to a memory cell that stores binary 00 but that is associated with a threshold voltage in the area labeled with reference number 435, current would flow, erroneously indicating that the lower page data represents a “1” rather than a “0”.

Similarly, as shown by reference number 440, when performing an upper page read, an upper page read error may be caused by the broadening of voltage distributions that are near V_{A} and/or V_{C} and/or that overlap with V_{A} and/or V_{C}. For example, memory cells storing binary 11 and associated with a threshold voltage in the area labeled by 445 may be erroneously read as storing upper page data of “0”, memory cells storing binary 01and associated with a threshold voltage in the area labeled by 450 may be erroneously read as storing upper page data of “1”, memory cells storing binary 00and associated with a threshold voltage in the area labeled by 455 may be erroneously read as storing upper page data of “1”, and memory cells storing binary 10and associated with a threshold voltage in the area labeled by 460 may be erroneously read as storing upper page data of “0”. Because performing an upper page read may include applying V_{C}, which may be a higher voltage than V_{B}, the likelihood of an upper page read error may be increased if a memory cell that stores a state associated with the voltage range 420 experiences a read disturbance charge loss (e.g., because the read disturbance induced charge loss may decrease the voltage of the memory cell). Accordingly, because a high temperature may cause a read disturbance induced charge loss, an upper page read error may be more likely to occur at a high temperature than a low temperature. Conversely, because performing a lower page read may include applying V_{B}, the likelihood of a lower page read error may not increase as result of read disturbance induced charge loss. Said another way, an upper page read may be more sensitive to high temperature related noise than a lower page read.

In some cases, a memory device may attempt to adjust one or more read reference voltages in response to one or more of the read errors described above (e.g., in response to a cell storing one logical value or binary number being misread as storing a different logical value or binary number). In some instances, this may be referred to as a read retry or a read recovery process. In a read recovery process, one or more read reference voltages (such as V_{A}, V_{B}, or V_{C} described in connection with the MLC) may be dynamically adjusted to track changes in threshold voltage distributions. More particularly, once a read process fails on a particular page of a memory, the memory device (and, more particularly, the controller and/or a read recovery component thereof) may attempt to recover the page using various read recovery steps, which use shifts in voltages from base read reference voltages. Put another way, the memory device may retry the read of a cell with an adjusted read reference voltage such that read errors are decreased or eliminated.

Returning to the example shown in FIG. 4, if a lower page error resulted in a cell storing binary 00 being read as binary 01, the read reference voltage (V_{B}) may be decreased (e.g., shifted to the left in the diagram shown by reference number 425) in an effort to eliminate the lower page read error. Conversely, if a lower page error resulted in a cell storing binary 01 being read as binary 00, the read reference voltage (V_{B}) may be increased (e.g., shifted to the right in the diagram shown by reference number 425). Similarly, the read reference voltages V_{A} and V_{C} may be shifted left or right (e.g., decreased or increased) in an effort to reduce or eliminate upper page read errors.

In some examples, the memory device may perform one or more read disturbance operations to account for errors due to read disturbance. For example, the memory device may perform one or more types of page scans, such as one or more lower page scans and/or one or more upper page scans. To perform a page scan, the memory device may select one or more word lines of a block of memory cells from a corresponding word line list (e.g., one or more tracked word lines), such as a lower page word line list corresponding to a lower page scan and/or an upper word line list corresponding to an upper page scan. The memory device may read data stored to the selected word line(s) and/or may read data stored to one or more word lines that are adjacent to respective selected word line(s). The memory device may determine one or more error rates, such as one or more bit error rates (BERs) and/or one or more read bit error rates (RBERs), for data read from the selected word line(s) (e.g., a respective error rate corresponding to each of the selected word lines). The memory device may compare the error rate(s) to a threshold. If at least one of the error rate(s) satisfies the threshold, then the memory device may transfer data from the block of memory cells to a separate block of memory cells, for example by performing a garbage collection or other memory management operation on the block.

The memory device may perform additional types of page scans based on the type of memory cell of the memory device. For example, if the memory device is a TLC non-volatile memory device (e.g., a TLC flash device), then a memory cell of the memory device may store a first bit associated with a lower page, a second bit associated with an upper page, and a third bit associated with an extra page. In such examples, the memory device may perform an extra page scan on one or more word lines of an extra page word line list managed by the memory device. Similar to an upper page read error, an extra page read error may be more likely to occur at a high temperature.

In some examples, the memory device may initiate the one or more read disturbance operations based on a quantity of access operations performed by the memory device. For example, the memory device may maintain an access counter. As part of performing a read operation (e.g., a read operation associated with a read command received from a host system and/or a read operation associated with an internal read command), the memory device may modify (e.g., increase by an amount) the value of the access counter. If the value of the access counter satisfies a first access threshold, which may be referred to as a read window, then the memory system may perform the one or more read disturbance operations. In some examples, the memory device may modify the first access threshold. For example, a host system may provide, and the memory device may obtain, a configuration message indicating a second access threshold. Based on, in response to, or otherwise associated with obtaining the configuration message, the memory device may modify the first access threshold to be the second access threshold.

In some examples, the memory device may maintain multiple access counters. For example, the memory device may maintain a respective access counter for one or more blocks of the memory device. In such examples, the memory device may modify the access counter for a given block as part of performing a read operation on the given block. Further, the memory device may perform one or more read disturbance operations on a given block based on the access counter corresponding to the given block satisfying the access threshold. Additionally, or alternatively, the memory device may maintain a respective access counter for one or more dies of the memory device. For example, the memory device may maintain a respective access counter for one or more dies of the memory device. In such examples, the memory device may modify the access counter for a given die as part of performing a read operation on the given die. Further, the memory device may perform one or more read disturbance operations on a given die based on the access counter corresponding to the given block satisfying the access threshold. In implementations in which the memory device maintains multiple access counters, the memory device may use a respective access threshold for each of the multiple counters. Such respective access thresholds may be equal (e.g., each access threshold may be the same value) or non-equal. Further, a host system may configure an access threshold for a given die and/or block, for example by indicating, via the configuration message, the given die and/or block.

The word line lists may be stored to metadata of the memory device. For example, the memory device may store a lower page word line list, an upper page word line list, and/or an extra page word line list. In some examples, the quantity of word lines in a word line list and/or the particular word lines included in the word line list, which may collectively be referred to as a configuration of the word line list, may be defined in accordance with firmware or other code of the memory device. Additionally, or alternatively, a configuration of a word line list may be defined by an external device, such as a host system (e.g., the host system 105). In such examples, the host system may provide, and the memory system may obtain, a configuration message. The configuration message may indicate a configuration for one or more word line lists. For example, a configuration message may indicate a quantity of word lines to be included in a word line list and/or may indicate particular word lines to be included in a word line list. Based on, in response to, or otherwise associated with obtaining a configuration message for a given word line list, the memory device may modify the given word line list, for example by adding and/or removing word lines from the given word line list in accordance with the configuration message.

As indicated above, FIG. 4 is provided as an example. Other examples may differ from what is described with regard to FIG. 4.

FIG. 5 is a diagram of an example 500 of temperature-based read disturb operations. The operations described in connection with FIG. 5 may be performed by a memory system (e.g., the memory system 110 and/or one or more components of the memory system 110, such as the memory system controller 115, one or more memory devices 120, one or more local controllers 125, and/or the memory device 302). Additionally, operations described in connection with FIG. 5 may be performed by the host system 105 and/or one or more components of the host system 105, such as the host processor 150 and/or the host interface 140.

The memory system may maintain a counter (e.g., an access counter) to track a quantity of read operations performed by the memory system. As part of performing a read operation (e.g., a read operation associated with a read command received from a host system and/or a read operation associated with an internal read command), the memory system may modify (e.g., increase by one or more amounts, as described herein) the value of the access counter. If the value of the counter satisfies an access threshold, then the memory system may perform the one or more read disturbance operations.

For example, as shown by reference number 505, the memory system may perform a read operation. In some examples, the memory system may perform the read operation in response to a read command obtained from a host system. Alternatively, the memory system may perform the read operation in response to an internal read command, such as a read command associated with a memory management operation. The read operation may include accessing a word line (e.g., a word line indicated by an address associated with the read command) to retrieve data stored to memory cells associated with the word line.

The memory system may identify a temperature associated with the word line as part of performing the read operation. The temperature may be the temperature of a block corresponding to the word line, the temperature of a die corresponding to the word line, and/or the temperature of the memory system. The memory system may read the temperature from one or more registers. Additionally, or alternatively, the memory system may perform a measurement to identify the temperature, for example by measuring the temperature of a block corresponding to the word line, measuring the temperature of a die corresponding to the word line, and/or measuring the temperature of the memory system.

The memory system may selectively modify the counter by a first value, or by a second value that is less than the first value, based on the temperature. As used herein, “selectively” performing an operation means to either perform the operation or refrain from performing the operation. For example, selectively performing an operation based on whether a condition is satisfied means that the operation is performed if the condition is satisfied and that the operation is not performed if the condition is not satisfied (or vice versa). Thus, selectively performing an operation may include determining whether to perform the operation and then either performing the operation or refraining from performing the operation based on that determination. As used herein, “selectively” performing a first operation or a second operation means to perform either the first operation or the second operation. For example, selectively performing a first operation or a second operation based on whether a condition is satisfied means that the first operation is performed if the condition is satisfied and that the second operation is performed if the condition is not satisfied (or vice versa). Thus, selectively performing a first operation or a second operation may include determining whether to perform either the first operation or the second operation and then performing either the first operation or the second operation based on that determination.

For example, as shown by reference number 510, the memory system may compare the temperature to a threshold to determine whether the temperature satisfies the threshold. As shown by reference number 515, if the temperature satisfies the threshold, then the memory system may modify (e.g., increase) the counter by the first value. Alternatively, as shown by reference number 520, if the temperature does not satisfy the threshold, then the memory system may modify (e.g., increase) the counter by the second value. Because the first value is greater than the second value, read operations on a word line associated with a high temperature (e.g., a temperature that satisfies the threshold) may increase the rate at which the counter increases. Accordingly, if the temperature is high, the memory system may perform read disturbance operations more frequently, which may increase the likelihood of identifying read errors (e.g., lower page read errors, upper page read errors, and/or extra page read errors) caused by the high temperature (e.g., errors caused by read disturbance induced charge loss). Accordingly, the memory system may more reliably address such errors (e.g., by transferring data from a block that includes the word line to a separate block), and thus improve the integrity of data stored to the memory system. Alternatively, if the temperature is low (e.g., if the temperature does not satisfy the threshold), then the memory system may perform read disturbance operations less frequently, which may reduce the processing load on the memory system and thus improve performance associated with performing other operations, such as host read and/or host write operations.

As shown by reference number 525, the memory system may determine whether the word line associated with the read operation is adjacent to a tracked word line. For example, the memory system may determine whether the word line is a neighboring word line of a word line included in one or more word line lists (e.g., a lower page word line list, an upper page word line list, and/or an extra page word line list). The memory system may compare a row address of the word line associated with the read operation to one or more row addresses of the word line list(s).

As shown by reference number 530, if the row address of the word line corresponds to a row address immediately before or immediately after at least one row address of a word line of the word line list(s), then the memory system may modify (e.g., increase) the counter by a third value. The third value may be greater than the second value. Additionally, the third value may be less than, equal to, or greater than the first value. By modifying the counter by the third value, the memory system may increase the frequency of read disturbance operations if word lines adjacent to tracked word lines are frequently accessed. Because an access operation on a word line may cause noise on adjacent word lines, and thus increase the likelihood of a read error, such read disturbance operations may be more likely to detect a read error in data associated with a tracked word line. Accordingly, the memory system may more reliably address such errors (e.g., by transferring data from a block that includes the word line to a separate block), and thus improve the integrity of data stored to the memory system.

In some implementations, the memory system may modify the threshold, the first value, the second value, and/or the third value. For example, a host system may provide, and the memory system may obtain, a configuration message indicating an updated threshold, an updated first value, an updated second value, and/or an updated third value. Based on, in response to, or otherwise associated with obtaining the configuration message, the memory device may modify the threshold, the first value, the second value, and/or the third value in accordance with the configuration message.

As indicated above, FIG. 5 is provided as an example. Other examples may differ from what is described with regard to FIG. 5.

FIG. 6 is a diagram of an example 600 of temperature-based read disturb operations. The operations described in connection with FIG. 6 may be performed by a memory system (e.g., the memory system 110 and/or one or more components of the memory system 110, such as the memory system controller 115, one or more memory devices 120, one or more local controllers 125, and/or the memory device 302). Additionally, operations described in connection with FIG. 6 may be performed by the host system 105 and/or one or more components of the host system 105, such as the host processor 150 and/or the host interface 140.

In some examples, the memory system may perform one or more read disturbance operations to account for errors due to read disturbance. For example, the memory system may perform one or more types of page scans, such as one or more lower page scans, one or more upper page scans, and/or one or more extra page scans, as described in greater detail in connection with the example shown in FIG. 4. To account for read errors caused by read disturbance charge gain, which may be more likely at low temperatures, and read errors caused by read disturbance induced charge loss, which may be more likely at high temperatures, the memory system may modify the one or more read disturbance operations based on one or more temperatures associated with the memory system.

The memory system may perform the one or more read disturbance operations based on one or more counters (e.g., one or more access counters) satisfying one or more thresholds. For example, the memory system may compare (e.g., periodically, as part of memory maintain acne operations) respective values of the one or more counters to respective thresholds of the one or more thresholds. If a counter satisfies a threshold, then the memory system may initiate the one or more read disturbance operations. In some implementations, the memory system may perform the one or more read disturbance operations on a component of the memory system which corresponds to the counter that satisfies the threshold. For example, if an access counter tracks a quantity of access operations for a given block of the memory system, and the access counter satisfies the corresponding threshold, then the memory system may perform the one or more read disturbance operations on the given block. Additionally, if an access counter tracks a quantity of access operations for a given die of the memory system, and the access counter satisfies the corresponding threshold, then the memory system may perform the one or more read disturbance operations on the given die.

As shown by reference number 605, the memory system may identify a temperature associated with the counter. The temperature may be the temperature of a block corresponding to the counter, the temperature of a die corresponding to the counter, and/or the temperature of the memory system. The memory system may read the temperature from one or more registers. Additionally, or alternatively, the memory system may perform a measurement to identify the temperature, for example by measuring the temperature of a block corresponding to the counter, measuring the temperature of a die corresponding to the counter, and/or measuring the temperature of the memory system.

The memory system may selectively perform one or more first read disturbance operations of a first type or may perform one or more second read disturbance operations of a second type based on the temperature. For example, as shown by reference number 610, the memory system may compare the temperature to a first threshold to determine whether the temperature satisfies the first threshold. The one or more first read disturbance operations may include performing one or more page scans having a first type (e.g., one or more extra page scans and/or one or more upper page scans). The one or more second read disturbance operations may include performing one or more page scans having a second type (e.g., one or more lower page scans).

As shown by reference number 615, if the temperature satisfies the first threshold, then the memory system may perform the one or more first read disturbance operations. In such examples, the memory system may refrain from performing the one or more second read disturbance operations. To perform the one or more first read disturbance operations, the memory system may select one or more word lines from a first word line list (e.g., an upper page word line list and/or an extra page word line list). In some examples, the memory system may select the one or more word lines randomly from the first word line list (e.g., using a random number generator, for example as part of a probabilistic read disturbance operation). Alternatively, the memory system may select the one or more word lines based on access statistics of the first word line list, such as by selecting word lines having an access parameter (e.g., an access count, an access frequency) that satisfies a threshold).

The memory system may perform the first type of page scan on the selected word line(s), as described in greater detail in connection with the example shown in FIG. 4. Because the first type of page scan may be more sensitive to page errors caused by read disturbance induced charge loss, by performing the one or more first read disturbance operations, the memory system may more reliably address such errors (e.g., by transferring data from a block(s) that includes the selected word line(s) to separate block(s)), and thus improve the integrity of data stored to the memory system.

In some examples, accessing a given word line may be more likely to cause noise on word lines adjacent to the given word lines, and thus cause page read errors, at higher temperatures (e.g., higher than the threshold). To account for such increased errors, the memory system may perform one or more additional page scans of the first type. For example, as shown by reference number 620, if the temperature satisfies a second threshold, then, as shown by reference number 625, the memory system may select one or more additional word lines associated with the first word line list. The second threshold may be greater than or equal to the first threshold. In some implementations, the additional word line(s) may be adjacent to word lines of the first word line list. For example, to select the additional word lines(s), the memory system may select one or both of the word lines adjacent to the word lines selected in connection with operations related to reference number 615. The memory system may perform one or more page scans on the additional selected word line(s). By performing the additional page scans based on the temperature satisfying the second threshold, the memory system may more reliably address errors caused by noise associated with accessing neighboring word lines, and thus improve the integrity of data stored to the memory system.

Alternatively, if the temperature does not satisfy the first threshold, then, as shown by reference number 630, the memory system may perform the one or more second read disturbance operations. In such examples, the memory system may refrain from performing the one or more first read disturbance operations. To perform the one or more second read disturbance operations, the memory system may select one or more word lines from a second word line list (e.g., the lower page word line list). In some examples, the memory system may select the one or more word lines randomly from the second word line list (e.g., using a random number generator, for example as part of a probabilistic read disturbance operation). Alternatively, the memory system may select the one or more word lines based on access statistics of the second word line list, such as by selecting word lines having an access parameter (e.g., an access count, an access frequency) that satisfies a threshold).

In some implementations, the likelihood of page errors caused by read disturbance charge gain may increase as the temperature decreases. To account for such page errors, the memory system may select all or a subset of the word lines of the second word line list based on the temperature. For example, if the temperature does not satisfy a third threshold (e.g., a threshold lower than the first threshold), then the memory system may select each word line of the second word line list. Alternatively, if the temperature satisfies the third threshold, the memory system may select a subset of the second word line list. By selecting each word line of the second word line list at lower temperatures, the memory system may more reliably address errors caused by read disturbance charge gain, and thus improve the integrity of data stored to the memory system.

The memory system may perform the second type of page scan on the selected word line(s), as described in greater detail in connection with the example shown in FIG. 4. By refraining from performing the one or more first read disturbance operations, the memory system may reduce the quantity of read disturbance operations performed at lower temperatures (e.g., lower than the threshold), which may reduce the processing load on the memory system and thus improve performance associated with performing other operations, such as host read and/or host write operations.

In some implementations, the memory system may modify the first threshold, the second threshold, the third threshold, the first word line list, and/or the second word line list. For example, a host system may provide, and the memory system may obtain, a configuration message indicating an updated first threshold, an updated second threshold, an updated third threshold, an updated first word line list, and/or an updated second word line list. Based on, in response to, or otherwise associated with obtaining the configuration message, the memory device may modify the first threshold, the second threshold, the third threshold, the first word line list, and/or the second word line list in accordance with the configuration message.

As indicated above, FIG. 6 is provided as an example. Other examples may differ from what is described with regard to FIG. 6.

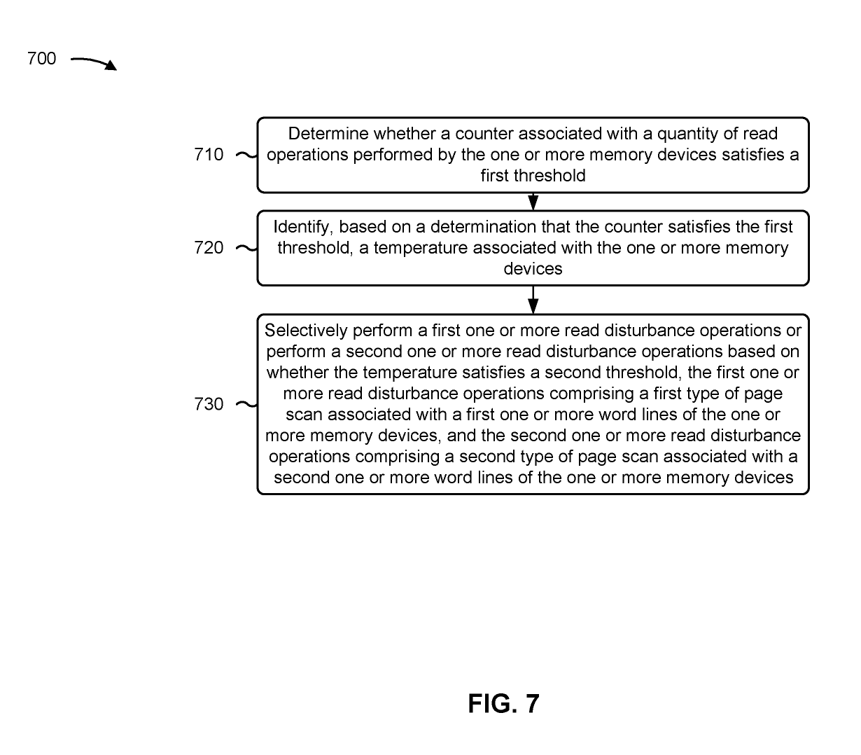

FIG. 7 is a flowchart of an example method 700 associated with temperature-based read disturb operations. In some implementations, a memory apparatus, such as the memory system 110, may perform or may be configured to perform the method 700. In some implementations, another device or a group of devices separate from or including the memory apparatus (e.g., the host system 105, the host processor 150, and/or the host interface 140) may perform or may be configured to perform the method 700. Additionally, or alternatively, one or more components of the memory apparatus (e.g., the memory system controller 115, one or more memory devices 120, one or more local controllers 125, one or more memory arrays 130, and/or one or more volatile memory arrays 135) may perform or may be configured to perform the method 700. Thus, means for performing the method 700 may include the memory apparatus and/or one or more components of the memory apparatus. Additionally, or alternatively, a non-transitory computer-readable medium may store one or more instructions that, when executed by the memory apparatus, cause the memory apparatus to perform the method 700.

As shown in FIG. 7, the method 700 may include determining whether a counter associated with a quantity of read operations performed by one or more memory devices satisfies a first threshold (block 710). As further shown in FIG. 7, the method 700 may include identifying, based on determining that the counter satisfies the first threshold, a temperature associated with the one or more memory devices (block 720). As further shown in FIG. 7, the method 700 may include selectively identifying a first one or more error rates using one or more page scans having a first type, the first one or more error rates associated with a first one or more pages of the one or more memory devices or identifying a second one or more error rates using one or more page scans having a second type, the second one or more error rates associated with a second one or more pages of the one or more memory devices based on determining whether the temperature satisfies a second threshold (block 730).

The method 700 may include additional aspects, such as any single aspect or any combination of aspects described below and/or described in connection with one or more other methods or operations described elsewhere herein.

In a first aspect, selectively identifying the first one or more error rates or identifying the second one or more error rates comprises identifying, based on determining that the temperature satisfies the second threshold, the first one or more error rates, and refraining, based on determining that the temperature satisfies the second threshold, from identifying the second one or more error rates.

In a second aspect, alone or in combination with the first aspect, selectively identifying the first one or more error rates or identifying the second one or more error rates comprises identifying, based on determining that the temperature does not satisfy the second threshold, the second one or more error rates, and refraining, based on determining that the temperature does not satisfy the second threshold, from identifying the first one or more error rates.

In a third aspect, alone or in combination with one or more of the first and second aspects, identifying the first one or more error rates comprises reading a first page of the first one or more pages, the first page associated with a first word line of one or more word lines, determining whether the temperature satisfies a third threshold, and reading, based on determining that the temperature satisfies the third threshold, a second page of the first one or more pages, the second page associated with a second word line of the one or more word lines, the second word line being adjacent to the first word line.

In a fourth aspect, alone or in combination with one or more of the first through third aspects, identifying the first one or more error rates comprises reading a first page of the first one or more pages, the first page associated with a first word line of the first one or more word lines, determining whether the temperature satisfies a third threshold, and refraining, based on determining that the temperature does not satisfy the third threshold, from reading a second page of the first one or more pages, the second page associated with a second word line of the first one or more word lines, the second word line being adjacent to the first word line.

Although FIG. 7 shows example blocks of a method 700, in some implementations, the method 700 may include additional blocks, fewer blocks, different blocks, or differently arranged blocks than those depicted in FIG. 7. Additionally, or alternatively, two or more of the blocks of the method 700 may be performed in parallel. The method 700 is an example of one method that may be performed by one or more devices described herein. These one or more devices may perform or may be configured to perform one or more other methods based on operations described herein.

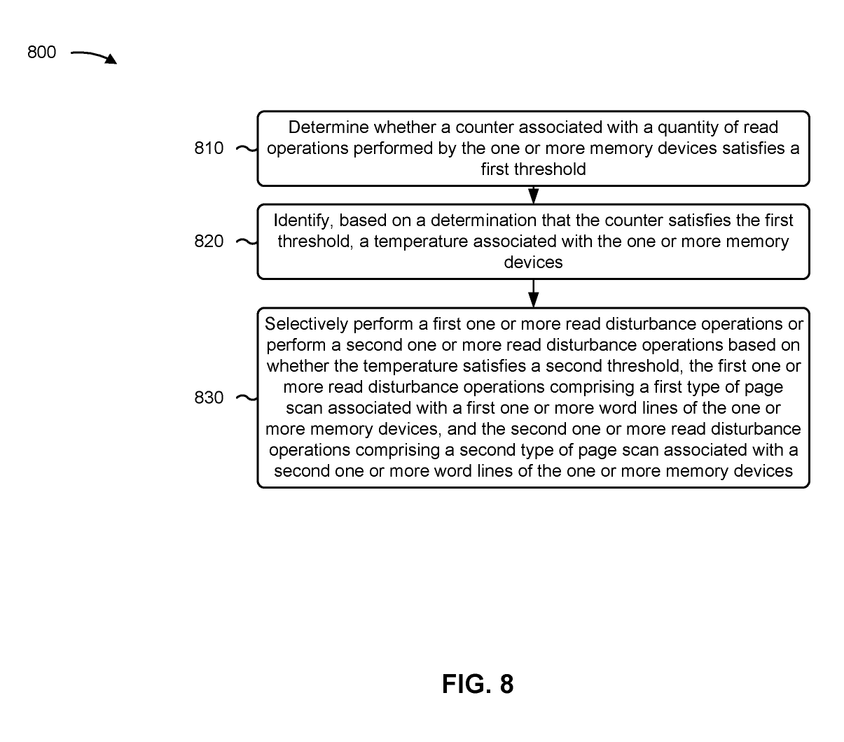

FIG. 8 is a flowchart of an example method 800 associated with temperature-based read disturb operations. In some implementations, a memory system (e.g., the memory system 110) may perform or may be configured to perform the method 800. In some implementations, another device or a group of devices separate from or including the memory system (e.g., the host system 105, the host processor 150, and/or the host interface 140) may perform or may be configured to perform the method 800. Additionally, or alternatively, one or more components of the memory system (e.g., the memory system controller 115, one or more memory devices 120, one or more local controllers 125, one or more memory arrays 130, and/or one or more volatile memory arrays 135) may perform or may be configured to perform the method 800. Additionally, or alternatively, a non-transitory computer-readable medium may store one or more instructions that, when executed by the memory system, cause the memory system to perform the method 800.

As shown in FIG. 8, the method 800 may include determining whether a counter associated with a quantity of read operations performed by the one or more memory devices satisfies a first threshold (block 810). As further shown in FIG. 8, the method 800 may include identifying, based on a determination that the counter satisfies the first threshold, a temperature associated with the one or more memory devices (block 820). As further shown in FIG. 8, the method 800 may include selectively performing a first one or more read disturbance operations or perform a second one or more read disturbance operations based on whether the temperature satisfies a second threshold, the first one or more read disturbance operations comprising a first type of page scan associated with a first one or more word lines of the one or more memory devices, and the second one or more read disturbance operations comprising a second type of page scan associated with a second one or more word lines of the one or more memory devices (block 830).

The method 800 may include additional aspects, such as any single aspect or any combination of aspects described below and/or described in connection with one or more other methods or operations described elsewhere herein.

In a first aspect, the temperature satisfies the second threshold, and selectively performing the first one or more read disturbance operations or the second one or more read disturbance operations comprises performing, based on the temperature satisfying the second threshold, the first one or more read disturbance operations, and refraining, based on the temperature satisfying the second threshold, from performing the second one or more read disturbance operations.

In a second aspect, alone or in combination with the first aspect, the temperature does not satisfy the second threshold, and selectively performing the first one or more read disturbance operations or the second one or more read disturbance operations comprises performing, based on the temperature not satisfying the second threshold, the second one or more read disturbance operations, and refraining, based on the temperature not satisfying the second threshold, from performing the first one or more read disturbance operations.

In a third aspect, alone or in combination with one or more of the first and second aspects, performing the first one or more read disturbance operations comprises scanning a first page associated with a first word line of the first one or more word lines, determining that the temperature satisfies a third threshold, and scanning, based on the temperature satisfying the third threshold, a second page associated with a second word line of the first one or more word lines, the second word line being adjacent to the first word line.

In a fourth aspect, alone or in combination with one or more of the first through third aspects, the method 800 includes scanning a first page associated with a first word line of the first one or more word lines, determining that the temperature does not satisfy a third threshold, and refraining, based on the temperature not satisfying the third threshold, from scanning a second page associated with a second word line of the first one or more word lines, the second word line being adjacent to the first word line.

In a fifth aspect, alone or in combination with one or more of the first through fourth aspects, performing the first one or more read disturbance operations comprises selecting a word line of the first one or more word lines, reading a page associated with the word line, determining that an error rate of the page satisfies an error threshold, and transferring, based on the error rate satisfying the error threshold, data from a first block of the one or more memory devices, the word line being included in the first block, to a second block of the one or more memory devices.

In a sixth aspect, alone or in combination with one or more of the first through fifth aspects, the method 800 includes obtaining, from a host system, a configuration message, and modifying, based on the configuration message, the first threshold.

In a seventh aspect, alone or in combination with one or more of the first through sixth aspects, the method 800 includes obtaining, from a host system, a configuration message, and configuring, based on the configuration message, at least one of a first word line list comprising the first one or more word lines or a second word line list comprising the second one or more word lines.

In an eighth aspect, alone or in combination with one or more of the first through seventh aspects, the first type of page scan is an extra page scan and the second type of page scan is a lower page scan.

In a ninth aspect, alone or in combination with one or more of the first through eighth aspects, the counter corresponds to a second quantity of read operations performed on a die of the one or more memory devices.

In a tenth aspect, alone or in combination with one or more of the first through ninth aspects, the counter corresponds to a second quantity of read operations performed on a block of the one or more memory devices.

Although FIG. 8 shows example blocks of a method 800, in some implementations, the method 800 may include additional blocks, fewer blocks, different blocks, or differently arranged blocks than those depicted in FIG. 8. Additionally, or alternatively, two or more of the blocks of the method 800 may be performed in parallel. The method 800 is an example of one method that may be performed by one or more devices described herein. These one or more devices may perform or may be configured to perform one or more other methods based on operations described herein.

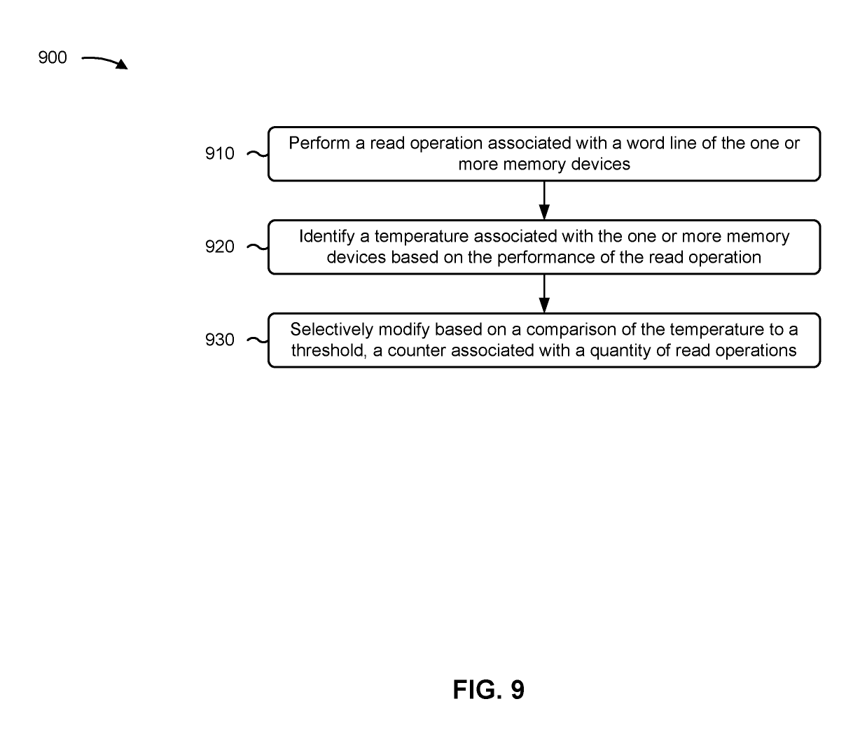

FIG. 9 is a flowchart of an example method 900 associated with temperature-based read disturb operations. In some implementations, a memory system (e.g., the memory system 110) may perform or may be configured to perform the method 900. In some implementations, another device or a group of devices separate from or including the memory system (e.g., the host system 105, the host processor 150, and/or the host interface 140) may perform or may be configured to perform the method 900. Additionally, or alternatively, one or more components of the memory apparatus (e.g., the memory system controller 115, one or more memory devices 120, one or more local controllers 125, one or more memory arrays 130, and/or one or more volatile memory arrays 135) may perform or may be configured to perform the method 900. Thus, means for performing the method 900 may include the memory system and/or one or more components of the memory system. Additionally, or alternatively, a non-transitory computer-readable medium may store one or more instructions that, when executed by the memory system, cause the memory system to perform the method 900.

As shown in FIG. 9, the method 900 may include performing a read operation associated with a word line of the one or more memory devices (block 910). As further shown in FIG. 9, the method 900 may include identifying a temperature associated with the one or more memory devices based on the performance of the read operation (block 920). As further shown in FIG. 9, the method 900 may include selectively modifying based on a comparison of the temperature to a threshold, a counter associated with a quantity of read operations (block 930).

The method 900 may include additional aspects, such as any single aspect or any combination of aspects described below and/or described in connection with one or more other methods or operations described elsewhere herein.

In a first aspect, selectively modifying the counter by the first value or the second value comprises increasing the counter by the first value based on a determination that the temperature satisfies the threshold.

In a second aspect, alone or in combination with the first aspect, selectively modifying the counter by the first value or the second value comprises increasing the counter by the second value based on a determination that the temperature does not satisfy the threshold.

In a third aspect, alone or in combination with one or more of the first and second aspects, the method 900 includes determining whether the word line is adjacent to a tracked word line of one or more tracked word lines of the one or more memory devices, and increasing, based on a determination that the word line is adjacent to the tracked word line, the counter by a third value.

In a fourth aspect, alone or in combination with one or more of the first through third aspects, the method 900 includes performing one or more read disturbance operations on the one or more memory devices based on a determination that the counter satisfies a second threshold.

Although FIG. 9 shows example blocks of a method 900, in some implementations, the method 900 may include additional blocks, fewer blocks, different blocks, or differently arranged blocks than those depicted in FIG. 9. Additionally, or alternatively, two or more of the blocks of the method 900 may be performed in parallel. The method 900 is an example of one method that may be performed by one or more devices described herein. These one or more devices may perform or may be configured to perform one or more other methods based on operations described herein.

In some implementations, a system includes one or more memory devices; and one or more controllers configured to: determine whether a counter associated with a quantity of read operations performed by the one or more memory devices satisfies a first threshold; identify, based on a determination that the counter satisfies the first threshold, a temperature associated with the one or more memory devices; and selectively perform a first one or more read disturb operations or perform a second one or more read disturb operations based on whether the temperature satisfies a second threshold, the first one or more read disturb operations comprising a first type of page scan associated with a first one or more word lines of the one or more memory devices, and the second one or more read disturb operations comprising a second type of page scan associated with a second one or more word lines of the one or more memory devices.

In some implementations, a system includes one or more memory devices; and one or more controllers configured to: perform a read operation associated with a word line of the one or more memory devices; identify a temperature associated with the one or more memory devices based on the performance of the read operation; and selectively modify, by a first value or a second value, based on a comparison of the temperature to a threshold, a counter associated with a quantity of read operations.

In some implementations, a method includes determining, by a memory apparatus, whether a counter associated with a quantity of read operations performed by one or more memory devices satisfies a first threshold; identifying, by the memory apparatus and based on determining that the counter satisfies the first threshold, a temperature associated with the one or more memory devices; and selectively identifying, by the memory apparatus, a first one or more error rates using one or more page scans having a first type, the first one or more error rates associated with a first one or more pages of the one or more memory devices or identifying a second one or more error rates using one or more page scans having a second type, the second one or more error rates associated with a second one or more pages of the one or more memory devices based on determining whether the temperature satisfies a second threshold.

In some implementations, a method includes determining, by a memory system, whether a counter associated with a quantity of read operations performed by the one or more memory devices satisfies a first threshold; identifying, based on a determination that the counter satisfies the first threshold, a temperature associated with the one or more memory devices; and selectively performing, by the memory system, a first one or more read disturbance operations or perform a second one or more read disturbance operations based on whether the temperature satisfies a second threshold, the first one or more read disturbance operations comprising a first type of page scan associated with a first one or more word lines of the one or more memory devices, and the second one or more read disturbance operations comprising a second type of page scan associated with a second one or more word lines of the one or more memory devices.

In some implementations, a method includes performing, by a memory system, a read operation associated with a word line of the one or more memory devices; identifying, by the memory system, a temperature associated with the one or more memory devices based on the performance of the read operation; and selectively modifying, by the memory system, based on a comparison of the temperature to a threshold, a counter associated with a quantity of read operations.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A system, comprising:
one or more memory devices; and
one or more controllers configured to:
determine whether a counter associated with a quantity of read operations performed by the one or more memory devices satisfies a first threshold;
identify, based on a determination that the counter satisfies the first threshold, a temperature associated with the one or more memory devices; and
selectively perform a first one or more read disturb operations or perform a second one or more read disturb operations based on whether the temperature satisfies a second threshold, the first one or more read disturb operations comprising a first type of page scan associated with a first one or more word lines of the one or more memory devices, and the second one or more read disturb operations comprising a second type of page scan associated with a second one or more word lines of the one or more memory devices.

2. The system of claim 1, wherein the temperature satisfies the second threshold, and wherein, to selectively perform the first one or more read disturb operations or the second one or more read disturb operations, the one or more controllers are configured to:
perform, based on the temperature satisfying the second threshold, the first one or more read disturb operations; and
refrain, based on the temperature satisfying the second threshold, from performing the second one or more read disturb operations.

3. The system of claim 1, wherein the temperature does not satisfy the second threshold, and wherein, to selectively perform the first one or more read disturb operations or the second one or more read disturb operations, the one or more controllers are configured to:
perform, based on the temperature not satisfying the second threshold, the second one or more read disturb operations; and
refrain, based on the temperature not satisfying the second threshold, from performing the first one or more read disturb operations.

4. The system of claim 1, wherein, to perform the first one or more read disturb operations, the one or more controllers are configured to:
scan a first page associated with a first word line of the first one or more word lines;
determine that the temperature satisfies a third threshold; and
scan, based on the temperature satisfying the third threshold, a second page associated with a second word line of the first one or more word lines, the second word line being adjacent to the first word line.

5. The system of claim 1, wherein, to perform the first one or more read disturb operations, the one or more controllers are configured to:
scan a first page associated with a first word line of the first one or more word lines;
determine that the temperature does not satisfy a third threshold; and
refrain, based on the temperature not satisfying the third threshold, from scanning a second page associated with a second word line of the first one or more word lines, the second word line being adjacent to the first word line.

6. The system of claim 1, wherein, to perform the first one or more read disturb operations, the one or more controllers are configured to:
select a word line of the first one or more word lines;
read a page associated with the word line;
determine that an error rate of the page satisfies an error threshold; and
transfer, based on the error rate satisfying the error threshold, data from a first block of the one or more memory devices, the word line being included in the first block, to a second block of the one or more memory devices.

7. The system of claim 1, wherein the one or more controllers are further configured to:
obtain, from a host system, a configuration message; and
modify, based on the configuration message, the first threshold.

8. The system of claim 1, wherein the one or more controllers are further configured to:
obtain, from a host system, a configuration message; and
configure, based on the configuration message, at least one of a first word line list comprising the first one or more word lines or a second word line list comprising the second one or more word lines.

9. The system of claim 1, wherein the first type of page scan is an extra page scan and the second type of page scan is a lower page scan.

10. The system of claim 1, wherein the counter corresponds to a second quantity of read operations performed on a die of the one or more memory devices.

11. The system of claim 1, wherein the counter corresponds to a second quantity of read operations performed on a block of the one or more memory devices.

12. A system, comprising:
one or more memory devices; and
one or more controllers configured to:
perform a read operation associated with a word line of the one or more memory devices;
identify a temperature associated with the one or more memory devices based on the performance of the read operation; and
selectively modify, by a first value or a second value, based on a comparison of the temperature to a threshold, a counter associated with a quantity of read operations.

13. The system of claim 12, wherein, to selectively modify the counter by the first value or the second value, the one or more controllers are configured to:
increase the counter by the first value based on a determination that the temperature satisfies the threshold.

14. The system of claim 12, wherein, to selectively modify the counter by the first value or the second value, the one or more controllers are configured to:
increase the counter by the second value based on a determination that the temperature does not satisfy the threshold.

15. The system of claim 12, wherein the one or more controllers are further configured to:
determine whether the word line is adjacent to a tracked word line of one or more tracked word lines of the one or more memory devices; and
increase, based on a determination that the word line is adjacent to the tracked word line, the counter by a third value.

16. The system of claim 12, wherein the one or more controllers are further configured to:
identify a second temperature associated with the one or more memory devices based on a determination that the counter satisfies a second threshold; and
perform one or more read disturb operations on the one or more memory devices based on a determination that the second temperature satisfies a third threshold.

17. A method, comprising:
determining, by a memory apparatus, whether a counter associated with a quantity of read operations performed by one or more memory devices satisfies a first threshold;
identifying, by the memory apparatus and based on determining that the counter satisfies the first threshold, a temperature associated with the one or more memory devices; and
selectively identifying, by the memory apparatus, a first one or more error rates using one or more page scans having a first type, the first one or more error rates associated with a first one or more pages of the one or more memory devices or identifying a second one or more error rates using one or more page scans having a second type, the second one or more error rates associated with a second one or more pages of the one or more memory devices based on determining whether the temperature satisfies a second threshold.

18. The method of claim 17, wherein selectively identifying the first one or more error rates or identifying the second one or more error rates comprises:
identifying, based on determining that the temperature satisfies the second threshold, the first one or more error rates; and
refraining, based on determining that the temperature satisfies the second threshold, from identifying the second one or more error rates.

19. The method of claim 17, wherein selectively identifying the first one or more error rates or identifying the second one or more error rates comprises:
identifying, based on determining that the temperature does not satisfy the second threshold, the second one or more error rates; and
refraining, based on determining that the temperature does not satisfy the second threshold, from identifying the first one or more error rates.

20. The method of claim 17, wherein identifying the first one or more error rates comprises:
reading a first page of the first one or more pages, the first page associated with a first word line of one or more word lines;
determining whether the temperature satisfies a third threshold; and
reading, based on determining that the temperature satisfies the third threshold, a second page of the first one or more pages, the second page associated with a second word line of the one or more word lines, the second word line being adjacent to the first word line.

21. The method of claim 17, wherein identifying the first one or more error rates comprises:
reading a first page of the first one or more pages, the first page associated with a first word line of the first one or more word lines;
determining whether the temperature satisfies a third threshold; and
refraining, based on determining that the temperature does not satisfy the third threshold, from reading a second page of the first one or more pages, the second page associated with a second word line of the first one or more word lines, the second word line being adjacent to the first word line.
